(19) United States
(12) Patent Application Publication
(10) Pub. No.: US 2013/0258307 A1
(43) Pub. Date: Oct. 3, 2013

(54) Magnet Array Configuration for Higher Efficiency Planar Motor

(71) Applicant: NIKON CORPORATION, Tokyo (JP)

(72) Inventors: Chetan Mahadeswaraswamy, San Francisco, CA (US); Michael B. Binnard, Belmont, CA (US); Shigeru Morimoto, Saitama (JP)

(73) Assignee: Nikon Corporation, Tokyo (JP)

(21) Appl. No.: 13/769,308

(22) Filed: Feb. 16, 2013

Related U.S. Application Data
(60) Provisional application No. 61/599,572, filed on Feb. 16, 2012.

(51) Int. Cl. G03F 7/20; H02K 41/03

(52) U.S. Cl. CPC G03F 7/70716; H02K 41/031
USPC 355/72; 310/12.06

(57) ABSTRACT

According to one aspect, a stage apparatus includes a first surface, a second surface, an overall magnet array, and a plurality of coils. The overall magnet array is mounted on the first surface, and includes an X magnet array and a Y magnet array. The coils are mounted on the second surface, and include a first coil that cooperates with the X magnet array to control force on the first surface along an x-axis. The coils also include a second coil that cooperates with the Y magnet array to control force on the first surface along a y-axis. The second coil cooperates with the overall magnet array to control force applied to the first surface in a direction normal to the first surface. The first coil does not cooperate with the overall magnet array to control the force applied in the direction normal to the first surface.

### CROSS REFERENCE TO RELATED APPLICATION

The present application claims benefit under 35 U.S.C. §119(e) of U.S. Provisional Patent Application No. 61/599,572, entitled “Magnet Array Configuration for Higher Efficiency Planar Motor,” filed Feb. 16, 2012, which is incorporated herein by reference in its entirety.

### BACKGROUND OF THE INVENTION

1. Field of the Invention

The present invention relates generally to equipment used in semiconductor processing. More particularly, the present invention relates to increasing the efficiency of an overall stage apparatus that includes a planar motor by utilizing a magnet array that is symmetric with respect to an x-axis and a y-axis such that either Y magnets may be used substantially alone or X magnets may be used substantially alone to provide for levitation relative to a z-axis, as well as to provide pitch compensation, and/or roll compensation.

2. Description of the Related Art

The precision and efficiency with which a stage system such as an exposure stage system operates may be compromised due to relatively large amounts of heat generated by actuators. For example, X-actuators that provide for a relatively high acceleration along an x-axis produce a relatively large amount of heat and Y-actuators that provide for a relatively high acceleration along a y-axis produce a relatively large amount of heat. When relatively large amounts of heat compromise the operation of an exposure stage system, the quality of wafers processed by the exposure stage system may be adversely affected. For example, when air surrounding a stage is heated, non-repeatable changes may be caused in a refractive index.

Further, the mass of X magnets and Y magnets of an overall magnet array that is part of an actuator arranged to drive a stage in a stage system may also adversely affect the precision and efficiency of the stage system. A heavier stage system is generally more difficult to activate, may have less favorable vibration characteristics, and typically has higher power requirements than a lighter stage system.

### SUMMARY OF THE INVENTION

The present invention pertains to a stage that includes an overall magnet array that is symmetric about both an x-axis and a y-axis, and utilizes Y actuators, e.g., Y magnets and Y coils, but not X actuators, e.g., X magnets and X coils, for levitation relative to a z-axis, pitch compensation, and/or roll compensation. Because X coils are used for acceleration along an x-axis and not for levitation, pitch and/or roll compensation, or acceleration along a y-axis, the amount of heat associated with X coils may be reduced. In one embodiment, X magnets and Y magnets may have different thicknesses in order to substantially minimize power consumption, as well as heat output from coils, by reducing the weight of a stage while allowing sufficient force to be produced in an x-direction, a y-direction, and a z-direction. The stage may be, for example, an exposure stage or a measurement stage.

According to one aspect, a stage apparatus includes a first surface, a second surface, an overall magnet array, and a plurality of coils. Typically, the first and second surfaces may be substantially parallel The overall magnet array is mounted on the first surface, and includes an X magnet array that includes at least one X magnet and a Y magnet array that includes at least one Y magnet. The plurality of coils is mounted on the second surface, and includes at least a first coil arranged to cooperate with the X magnet array to control force on the first surface along an x-axis. The plurality of coils also includes at least a second coil arranged to cooperate with the Y magnet array to control force on the first surface along a y-axis. The at least one second coil is further arranged to cooperate with the overall magnet array to control force applied to the first surface in a direction normal to the first surface. Although the at least first coil may be arranged so that it has a capability to cooperate with the overall magnet array to control the force applied to the first surface in the direction normal to the first surface, it is generally not utilized to generated substantial force normal to the first surface. In this way, the full power capability of the at least first coil is available for creating force along the x-axis. In one embodiment, the first surface is a surface of a stage.

In accordance with another aspect, a stage apparatus includes a first surface, a second surface, an overall magnet array mounted on the first surface, and a plurality of coils mounted on the second surface. The overall magnet array includes an X magnet array and a Y magnet array. The X magnet array includes at least one X magnet and the Y magnet array includes at least one Y magnet. The plurality of coils includes at least a first coil arranged to cooperate with the X magnet array to control force on the first surface along an x-axis, and at least a second coil arranged to cooperate with the Y magnet array to control force on the first surface along a y-axis. Forces applied to the first surface relative to a z-axis are applied through cooperation between the at least first coil and the overall magnet array. The at least one second coil is not activated to cooperate with the overall magnet array when the forces applied to the first surface relative to the z-axis are applied through the cooperation between the at least one first coil and the overall magnet array. In one embodiment, the overall magnet array is symmetric with respect to the x-axis and with respect to the y-axis.

According to still another aspect of the present invention, a stage apparatus includes a first surface, a second surface, an overall magnet array, and a plurality of coils. The overall magnet array is mounted on the first surface, and an X magnet array and a Y magnet array. The X magnet array includes at least one X magnet, and the Y magnet array includes at least one Y magnet. The plurality of coils is mounted on the second surface, and includes at least one X coil and at least one Y coil. The at least one X coil is arranged to cooperate with the X magnet array to cause the first surface to accelerate along an x-axis, and the at least one Y coil is arranged to cooperate with the Y magnet array to cause the first surface to accelerate along a y-axis, to levitate with respect to a z-axis, and to provide pitch and roll compensation. The at least one X coil does not cooperate with the X magnet array to cause the first surface to accelerate along the y-axis, to levitate with respect to the z-axis, and to provide the pitch and roll compensation.

### BRIEF DESCRIPTION OF THE DRAWINGS

The invention will be readily understood by the following detailed description in conjunction with the accompanying drawings, in which:

FIG. 1A is a diagrammatic representation of a stage system that includes magnet arrays that are symmetric with respect to an x-axis and a y-axis, and mounted on stages, in accordance with an embodiment of the present invention.

FIG. 1B is a diagrammatic representation of a stage system that includes at least one magnet array that is symmetric with respect to an x-axis and a y-axis, and cooperates with coil arrays mounted on stages, in accordance with an embodiment of the present invention.

FIG. 2 is a diagrammatic representation of a magnet array that is symmetric with respect to an x-axis and a y-axis, and is configured to support relatively high acceleration of a stage along the x-axis in accordance with an embodiment of the present invention.

FIG. 3 is a diagrammatic representation of a magnet array that is symmetric with respect to an x-axis and a y-axis, and is configured to support relatively high acceleration of a stage along the y-axis in accordance with an embodiment of the present invention.

FIG. 4A is a diagrammatic top-view representation of a magnet array that is symmetric with respect to an x-axis and a y-axis, is configured to support relatively high acceleration of a stage along the x-axis, and has magnets of different thicknesses in accordance with an embodiment of the present invention.

FIG. 4B is a diagrammatic side-view representation of a magnet array that is symmetric with respect to an x-axis and a y-axis, is configured to support relatively high acceleration of a stage along the x-axis, and has magnets of different thicknesses, e.g., magnet array 406 of FIG. 4A, in accordance with an embodiment of the present invention.

FIG. 5A is a diagrammatic top-view representation of a magnet array that is symmetric with respect to an x-axis and a y-axis, is configured to support relatively high acceleration of a stage along the y-axis, and has magnets of different thicknesses in accordance with an embodiment of the present invention.

FIG. 5B is a diagrammatic side-view representation of a magnet array that is symmetric with respect to an x-axis and a y-axis, is configured to support relatively high acceleration of a stage along the y-axis, and has magnets of different thicknesses, e.g., magnet array 506 of FIG. 5A, in accordance with an embodiment of the present invention.

FIG. 6A is a diagrammatic representation of a first coil array in which X coils and Y coils are arranged in adjacent layers relative to a z-axis in accordance with an embodiment of the present invention.

FIG. 6B is a diagrammatic representation of a second coil array in which X coils and Y coils are arranged in adjacent layers relative to a z-axis in accordance with an embodiment of the present invention.

FIG. 7 is a diagrammatic representation of a coil array in which groups of X coils and groups of Y coils are adjacent to each other in an xy-plane in accordance with an embodiment of the present invention.

FIGS. 8A and 8B are a process flow diagram which illustrates a method of driving and controlling a stage, e.g., a stage that is arranged to have greater acceleration in an x-direction than in a y-direction, in accordance with an embodiment of the present invention.

FIG. 9 is a diagrammatic representation of a photolithography apparatus in accordance with an embodiment of the present invention.

FIG. 10 is a process flow diagram which illustrates the steps associated with fabricating a semiconductor device in accordance with an embodiment of the present invention.

FIG. 11 is a process flow diagram which illustrates the steps associated with processing a wafer, i.e., step 1104 of FIG. 10, in accordance with an embodiment of the present invention.

FIG. 12A is a diagrammatic representation of a first magnet array that is symmetric with respect to an x-axis and a y-axis, and is configured to support relatively high acceleration of a stage along the x-axis in which Y magnets are split in accordance with an embodiment of the present invention.

FIG. 12B is a diagrammatic representation of an alternative magnet array that is symmetric with respect to an x-axis and a y-axis, and is configured to support relatively high acceleration of a stage along the x-axis in accordance with an embodiment of the present invention.

FIG. 12C is a diagrammatic representation of a second magnet array that is symmetric with respect to an x-axis and a y-axis, and is configured to support relatively high acceleration of a stage along the x-axis in which Y magnets are split in accordance with an embodiment of the present invention.

FIG. 13A is a diagrammatic representation of a first magnet array that is symmetric with respect to an x-axis and a y-axis, and is configured to support relatively high acceleration of a stage along the y-axis in which X magnets are split in accordance with an embodiment of the present invention.

FIG. 13B is a diagrammatic representation of an alternative magnet array that is symmetric with respect to an x-axis and a y-axis, and is configured to support relatively high acceleration of a stage along the y-axis in accordance with an embodiment of the present invention.

FIG. 13C is a diagrammatic representation of a second magnet array that is symmetric with respect to an x-axis and a y-axis, and is configured to support relatively high acceleration of a stage along the y-axis in which X magnets are split in accordance with an embodiment of the present invention.

### DETAILED DESCRIPTION OF THE INVENTION

Example embodiments of the present invention are discussed below with reference to the various figures. However, those skilled in the art will readily appreciate that the detailed description given herein with respect to these figures is for explanatory purposes, as the invention extends beyond these embodiments.

High heat generated by coils of planar motors, e.g., planar motors that have quadrant based magnet arrays which contain X magnets and Y magnets, used to drive a stage of a stage system often has an adverse effect on the performance of the stage system. For example, heat generated by coils may deform structures due to a thermal load, and/or heat generated by coils may change a refractive index of air surrounding a stage by changing a temperature which, in turn, may affect the accuracy of stage position measurement systems such as interferometers, encoders, etc. As such, reducing the amount of heat generated by coils of a planar motor that drives a stage of a stage system may improve the performance of the stage system.

To reduce heat generated by coils of a planar motor used to drive a stage, an overall magnet array of the planar motor may be configured to be substantially symmetric about both an x-axis and a y-axis. A planar motor or actuator which includes a symmetric magnet array may be such that coils which provide force in a direction in which a relatively large amount of force are not activated to provide force in any other direction. For example, when a planar motor is configured to provide a relatively large amount of force along an x-axis, X magnets of a symmetric magnet array may cooperate with X coils of a coil array to provide force along the x-axis, while Y magnets of the magnet array may cooperate with Y coils of the coil array to provide force along a y-axis and a z-axis substantially without any contribution from X coils. When a magnet array of a planar motor used to drive a stage is symmetric with respect to an x-axis and a y-axis, either X coils or Y coils may be used to control levitation, pitch, and/or roll, as the symmetry of the magnet array reduces the likelihood that the stage may be subjected to a twisting motion. Pitch is typically a rotation about a y-axis, and roll is typically a rotation about an x-axis. It should be appreciated that in some instances, both X coils and Y coils may be used to control levitation, with either the X coils or the Y coils taking the majority of the load. For example, Y magnets and Y coils may take up approximately ninety percent of a load relating to controlling levitation, while X magnets and X coils may take up approximately ten percent of the load relating to controlling levitations substantially without imparting a twisting moment on a stage.

When coils which are activated to impart relatively significant force, e.g., to provide a relatively high amount of acceleration, to a stage in a particular direction are substantially used only to provide the relatively significant force, and are not activated to provide levitation or to compensate for pitch and/or roll motion, the amount of heat generated by the coils may be reduced. The levitation is generally movement relative to a z-axis. By way of example, not utilizing X magnets and X coils for providing levitation, pitch, and/or roll compensation, the amount of heat associated dissipated in the X coils may be reduced. In addition, approximately the maximum possible force along an x-axis may be increased because substantially all available current may be used. More generally, the accuracy and efficiency with which a stage operates may be enhanced by reducing the amount of heat produced by coils which are arranged to provide relatively large amounts of force to enable a stage to accelerate.

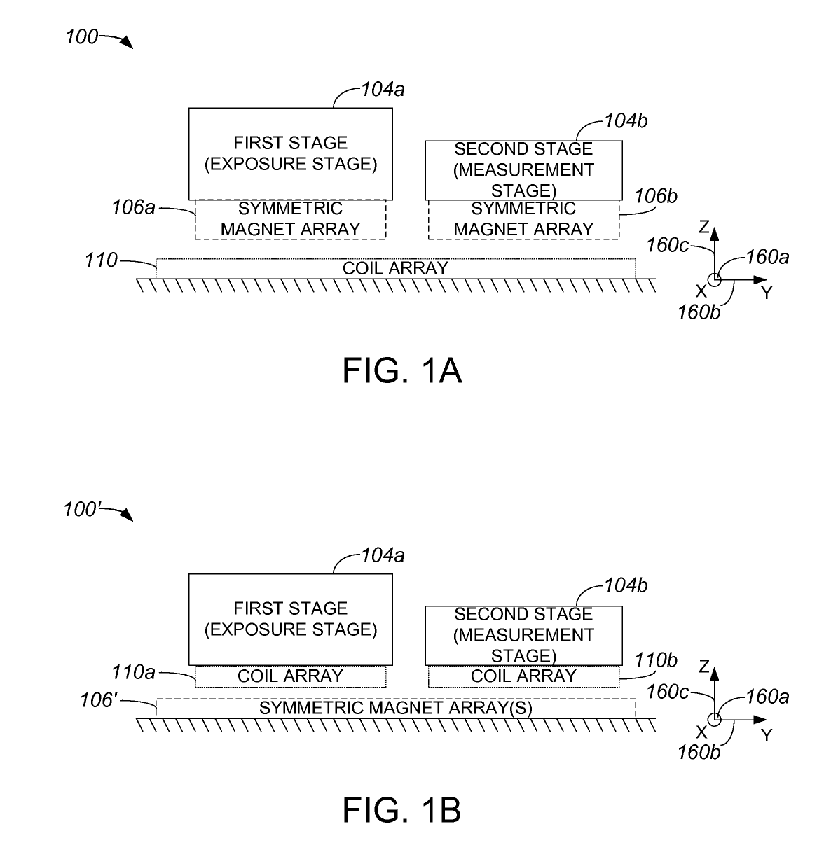

Referring initially to FIG. 1A, a stage system that includes magnet arrays that are symmetric with respect to an x-axis and a y-axis, and mounted on stages, will be described in accordance with an embodiment of the present invention. A stage system 100, which is generally a party of a photolithography apparatus, includes a first stage 104a and a second stage 104b. In the described embodiment, first stage 104a is an exposure stage and second stage 104b is a measurement stage. It should be appreciated, however, that first stage 104a is not limited to being an exposure stage and second stage 104b is not limited to being a measurement stage. Furthermore, stage system 100 is not limited to including two stages. For example, a stage system may include substantially only a single stage, or a stage system may include more than two stages.

A first symmetric magnet array 106a is carried by first stage 104a, e.g., coupled to a surface of first stage 104a. First symmetric magnet array 106a includes X magnets (not shown) and Y magnets (not shown) which are arranged such that the X magnets and Y magnets are symmetric with respect to both an x-axis 160a and a y-axis 160b. A second symmetric magnet array 106b is carried by second stage 104b, and also includes X magnets (not shown) and Y magnets (not shown) which are symmetric with respect to both x-axis 160a and y-axis 160b.

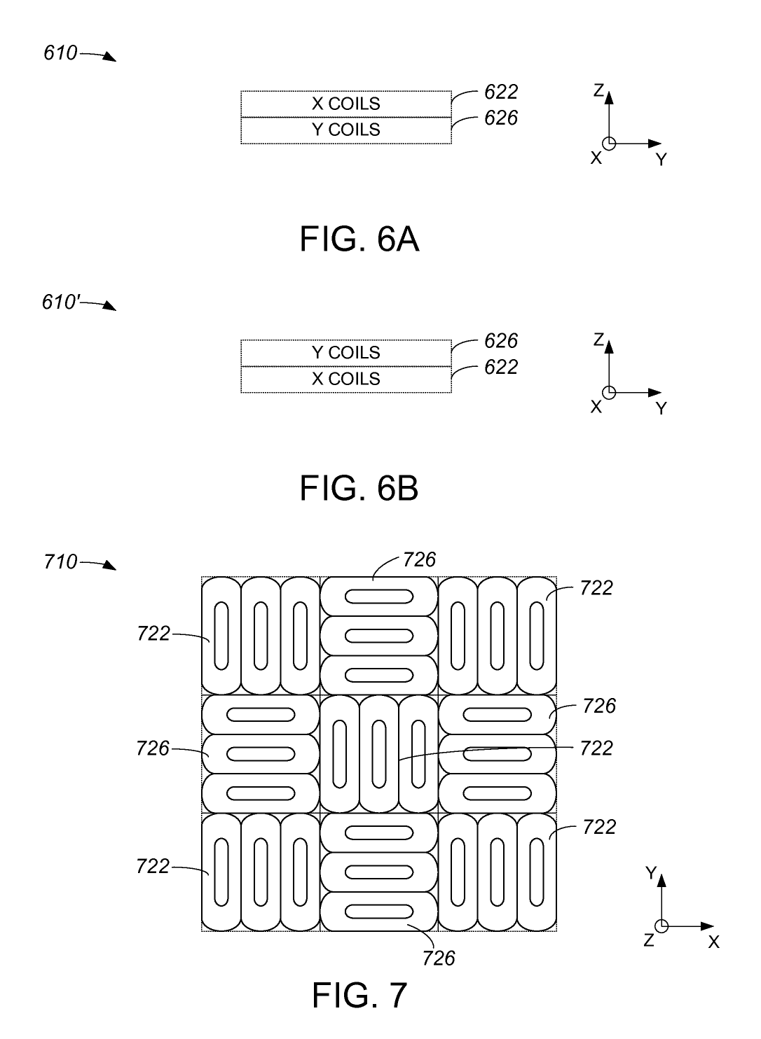

A coil array 110, which generally contains X coils (not shown) and Y coils (not shown), is positioned at a distance from symmetric magnet arrays 106a, 106b relative to a z-axis 160c. Coil array 110 may generally be coupled to any suitable surface within stage system 100. As will be discussed below with reference to FIGS. 6A, 6B, and 7, the orientation of X coils (not shown) and Y coils (not shown) with coil array 110 may vary. Coil array 110 and symmetric magnet arrays 106a, 106b are part of a planar motor. X magnets (not shown) within symmetric magnet arrays 106a, 106b are oriented such that when X coils (not shown) in coil array 110 are activated, stages 104a, 104b may translate along x-axis 160a. Similarly, Y magnets (not shown) within symmetric magnet arrays 106a, 106b are oriented such that when Y coils (not shown) in coil array 110 are activated, stages 104a, 104b may translate along y-axis 160b.

The planar motor that includes coil array 110 and symmetric magnet arrays 106a, 106b operates with a relatively high efficiency, as the symmetry of X magnets (not shown) and Y magnets (not shown) included in symmetric magnet arrays 106a, 106b allows the use of either substantially only X coils (not shown) in coil array 110 or substantially only Y coils (not shown) in coil array 110 to control levitation or linear movement of a stage 104a, 104b relative to z-axis 160c, e.g., in a direction normal to a plane defined by x-axis 160a and y axis 160b. By using one set of coils, e.g., either substantially only X coils (not shown) or substantially only Y coils (not shown), of a planar motor to control levitation as well as pitch and/or roll of a stage 104a, 104b, the amount of heat generated by the planar motor may be reduced. In addition, with the use of symmetric magnet arrays 106a, 106b, excitation of resonant vibration modes, e.g., a twisting mode, may be reduced in stages 104a, 104b. It should be appreciated that even in an embodiment in which substantially only X coils (not shown) or substantially only Y coils (not shown) are used to control levitation, pitch, and/or roll, a resonant vibration mode is generally not excited.

While a higher efficiency planar motor may include symmetric magnet arrays 106a, 106b that are coupled to surfaces of stages 104a, 104b, a higher efficiency planar motor may instead include coil arrays that are coupled to surfaces of stages. FIG. 1B is a diagrammatic representation of a stage system that includes at least one magnet array that is symmetric with respect to an x-axis and a y-axis, and cooperates with coil arrays mounted on stages, in accordance with an embodiment of the present invention. A stage system 100′ includes first stage 104a and second stage 104b.

A first coil array 110a is carried by first stage 104a, e.g., coupled to a surface of first stage 104a. First coil array 110a includes X coils (not shown) and Y coils (not shown). A second coil array 110b is carried by second stage 104b, and also includes X coils (not shown) and Y coils (not shown).

At least one symmetric magnet array 106′ is positioned at a distance away from coil arrays 110a, 110b relative to z-axis 160c. It should be understood that depending upon a specific application, a single symmetric magnet array 106′ may be shared by both stages 104a, 104b, or, alternatively, at least one symmetric magnet array 106′ may comprise two sub-arrays (not shown) which are each symmetric and which each cooperate with substantially only one of stages 104a, 104b. At least one symmetric magnet array 106′ and coil arrays 110a, 110b are part of a planar motor that drives first stage 104a and second stage 104b. X magnets (not shown) and Y magnets (not shown) in at least one symmetric magnet array 106′ are oriented such that the orientation of X magnets and Y magnets is symmetric with respect to x-axis 160a and y-axis 160b.

In general, within a symmetric magnet array, magnets may be oriented such that magnets associated with a direction of movement in which there is typically relatively high acceleration are positioned about a center of the symmetric magnet array, and magnets which are used to control levitation, pitch, and/or roll may be positioned at the outer edges of the symmetric magnet array. As such, for use with a stage that typically has a higher acceleration in an x-direction than in a y-direction, X magnets may be positioned about a center of a symmetric magnet array. Similarly, for use with a stage that typically has a higher acceleration in a y-direction than in an x-direction, Y magnets may be positioned about a center of a symmetric magnet array while X magnets are positioned at the edges of the symmetric magnet array. It should be appreciated that stages within a stage system may be such that each of the stages has a symmetric magnet array configured to support a higher acceleration in the same direction. Alternatively, one of the stages in a stage system may have a symmetric magnet array configured to support a higher acceleration in one direction while another stage in the stage system may have a symmetric magnet array configured to support a higher acceleration in a different direction. For some applications, one of the stages in a stage system may have an asymmetric or rotationally symmetric magnet array. In other words, a stage system may include any number of stages which are driven by a planar motor that includes a symmetric magnet array, and may also include one or more stages that are not driven by a planar motor that includes a symmetric magnet array.

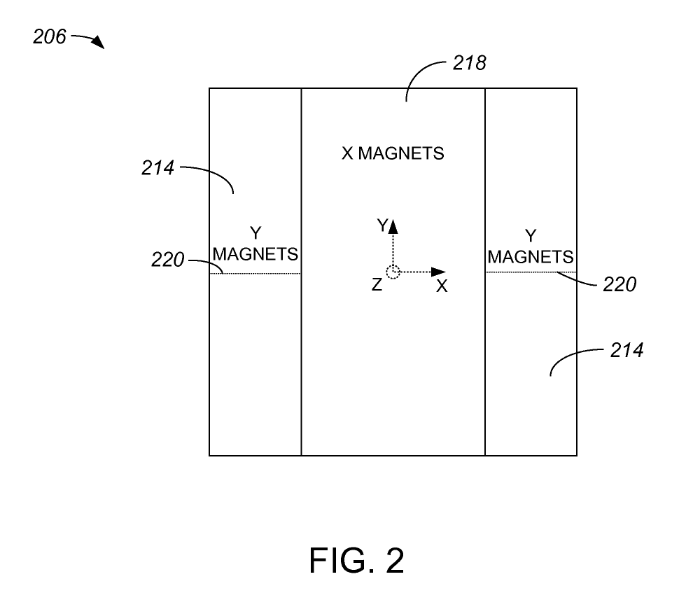

FIG. 2 is a diagrammatic representation of an overall magnet array that is symmetric with respect to an x-axis and a y-axis, and is configured to support relatively high acceleration along the x-axis in accordance with an embodiment of the present invention. An overall symmetric magnet array 206 includes Y magnet arrays or sub-arrays 214 and an X magnet array or sub-array 218. Y magnet sub-arrays 214 are arranged at the sides of symmetric magnet array 206, while X magnet sub-array 218 is located between Y magnet sub-arrays 214. In one embodiment, symmetric magnet array 206 may be particularly suitable for use with an exposure stage (not shown) that has a relatively high acceleration in an x-direction or along an x-axis. A planar motor that includes symmetric magnet array 206 and a coil array (not shown) is generally configured to generate force that provides a relatively high acceleration in an x-direction.

Each magnet sub-array 214, 218 generally includes a plurality of magnets (not shown). X magnet sub-array 218 includes a plurality of X magnets (not shown) oriented to cooperate with X coils of a coil array (not shown) to provide translational movement, and a relatively high acceleration, in an x-direction or along an x-axis. Y magnet sub-arrays 214 each include a plurality of Y magnets (not shown) oriented to cooperate with Y coils of a coil array (not shown) to provide translational movement in a y-direction or along a y-axis, as needed. Y magnet sub-arrays 214 are also arranged to cooperate with Y coils of a coil array (not shown) to provide a levitating force with respect to a z-axis, as well as to control pitching movement and/or rolling movement, e.g., rotational movement about a y-axis and/or rotational movement about an x-axis. Further, Y magnet sub-arrays 214 may be arranged to cooperate with Y coils of a coil array (not shown) to provide a yawing force about a z-axis by utilizing two forces generated by each Y magnet sub-array 214. As will be appreciated by those skilled in the art, rotation about an x-axis and a z-axis may be controlled by creating differential Z forces and differential Y forces, respectively, from Y magnet sub-arrays 214. Rotation about an x-axis may be controlled by further dividing each Y magnet sub-array 214 into two portions along a line 220 parallel to the x-axis and creating differential Z forces between the two portions of each Y magnet sub-array 214.

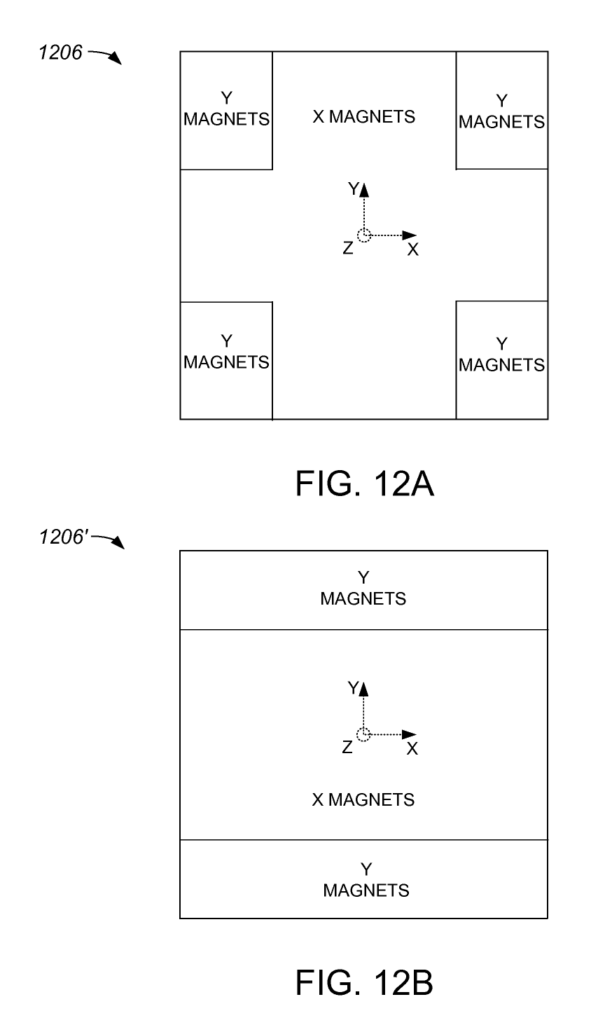

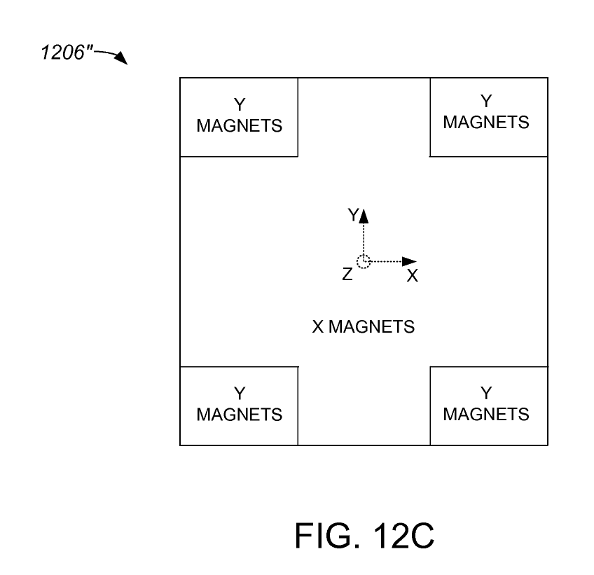

Alternate embodiments of a symmetric magnet array that is configured to support relatively high acceleration along an x-axis are shown in FIGS. 12A-12C. A symmetric magnet array 1206 of FIG. 12A includes Y magnets which are split, a symmetric magnet array 1206′ of FIG. 12B includes Y magnets that are arranged in an alternative orientation, and a symmetric magnet array 1206″ of FIG. 12C includes Y magnets which are split.

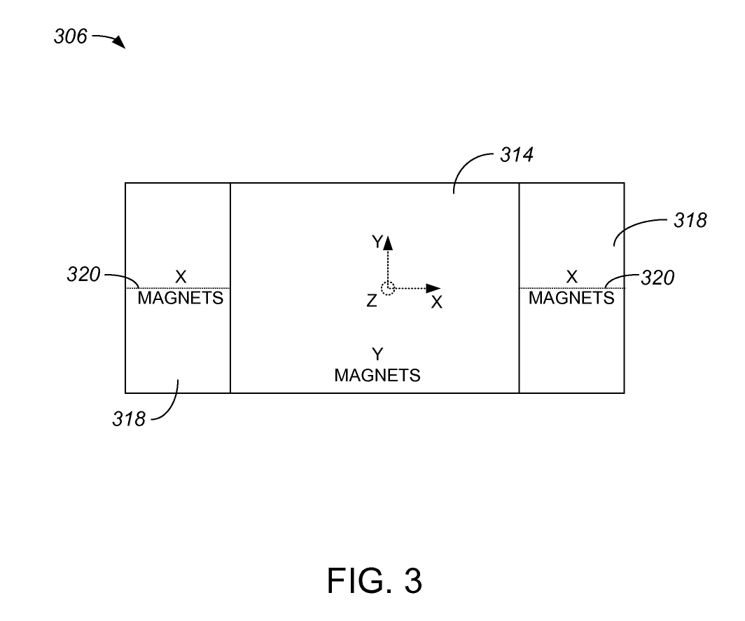

FIG. 3 is a diagrammatic representation of an overall magnet array that is symmetric with respect to an x-axis and a y-axis, and is configured to support relatively high acceleration along the y-axis in accordance with an embodiment of the present invention. An overall symmetric magnet array 306 includes X magnet sub-arrays 318 and a Y magnet sub-array 314. X magnet sub-arrays 318 are arranged at the sides of symmetric magnet array 306, while Y magnet sub-array 314 is located between X magnet sub-arrays 218. The configuration of symmetric magnet array 306 is such that a relatively high acceleration along a y-axis is supported. In one embodiment, symmetric magnet array 306 may be particularly suitable for use with respect to a measurement stage (not shown).

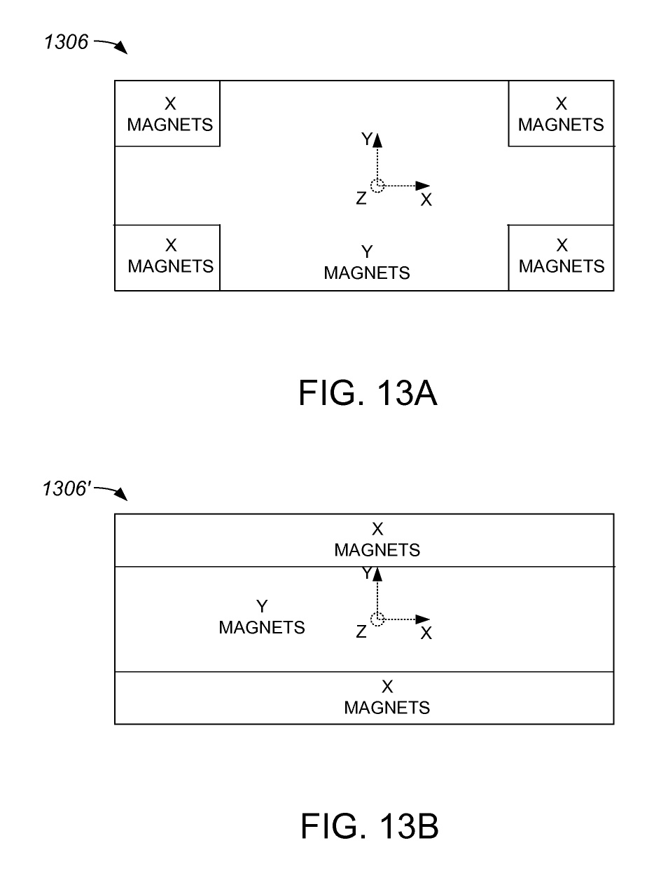

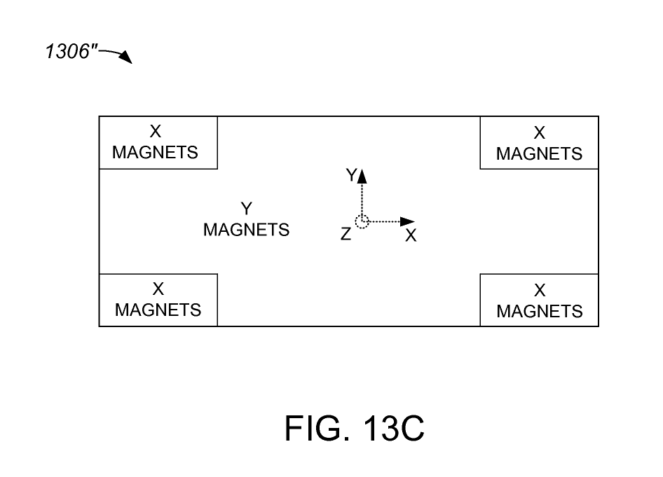

Each magnet sub-array 314, 318 generally includes a plurality of magnets (not shown). Y magnet sub-array 314 includes a plurality of Y magnets (not shown) oriented to cooperate with Y coils of a coil array (not shown) to provide force that may impart a relatively high acceleration in a y-direction or along a y-axis. X magnet sub-arrays 318 each include a plurality of X magnets (not shown) oriented to cooperate with X coils of a coil array (not shown) to provide translational movement in an x-direction or along an x-axis, as needed. X magnet sub-arrays 318 are also arranged to cooperate with X coils of a coil array (not shown) to provide a levitating force with respect to a z-axis, as well as to control pitching movement and/or rolling movement, e.g., rotational movement about a y-axis and/or rotational movement about an x-axis. Further, X magnet sub-arrays 318 may be arranged to cooperate with X coils of a coil array (not shown) to provide a yawing force about a z-axis by utilizing two forces generated by each X magnet sub-array 318 similarly to the structure shown in FIG. 2. As will be appreciated by those skilled in the art, rotation about a y-axis and a z-axis may be controlled by creating differential Z forces and differential X forces, respectively, from X magnet sub-arrays 318. Rotation about a y-axis may be controlled by further dividing each X magnet sub-array 318 into two portions along a line 320 parallel to the x-axis and creating differential Z forces using the portions of X magnet sub-arrays 318. Alternate embodiments of a symmetric magnet array that is configured to support relatively high acceleration along a y-axis are shown in FIGS. 13A-13C. A symmetric magnet array 1306 of FIG. 13A includes X magnets which are split, a symmetric magnet array 1306′ of FIG. 13B includes X magnets that are arranged in an alternative orientation, and a symmetric magnet array 1306″ of FIG. 13C includes X magnets which are split.

A symmetric magnet array that is part of a planar motor which drives a stage generally includes magnets which have substantially the same thicknesses. It should be appreciated, however, that a symmetric magnet array may include magnets of different thicknesses. In general, the thickness of a magnet that is included in a symmetric magnet array of a planar motor is a function of an amount of force that is to be provided by the magnet in cooperation with a coil. By way of example, if a force requirement relative to an x-direction is greater than a force requirement relative to a y-direction, then the thickness of an X magnet may be thicker than the thickness of a Y magnet. As a first mode of resonance, which is generally a twisting mode, is generally not significantly excited in a stage when a planar motor with a symmetric orientation of magnets is used to drive the stage, the thicknesses of X magnets and Y magnets within a symmetric magnet array of a planar motor may be different without adversely affecting the operation of the stage.

Reducing the thicknesses of some magnets of a symmetric magnet array reduces the mass associated with a stage on which the symmetric magnet array is mounted or otherwise carried. For example, when a symmetric magnet array is mounted on a stage that generally has a relatively high acceleration along an x-axis, the thickness of Y magnets in the magnet array may be less than the thickness of X magnets in the magnet array.

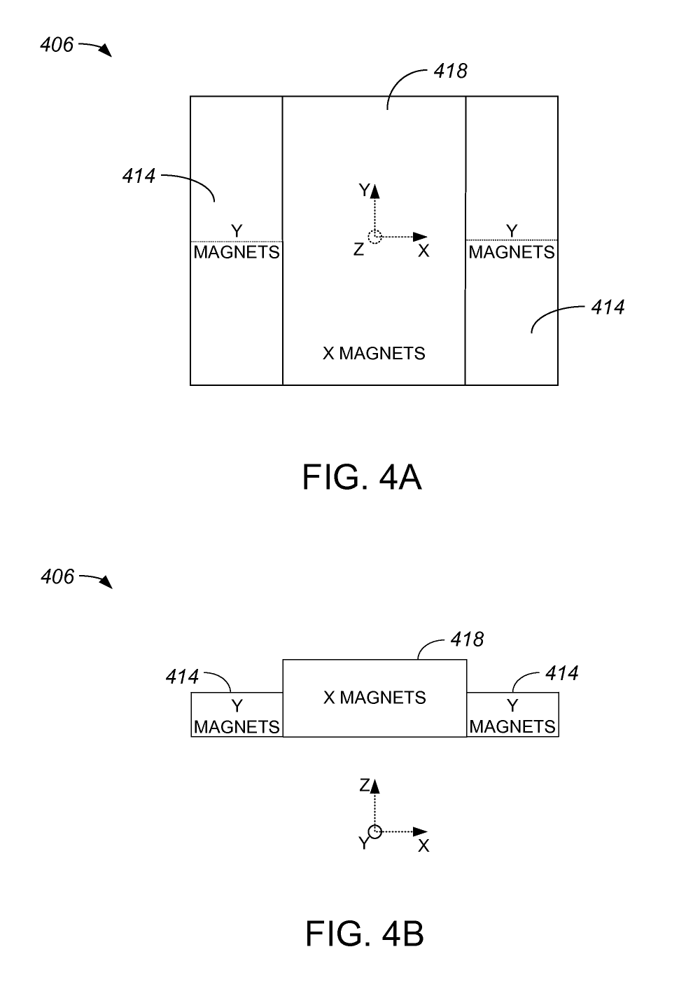

With reference to FIGS. 4A and 4B, a symmetric magnet array that is configured to support relatively high acceleration of a stage along an x-axis, and has magnets of different thicknesses, will be described in accordance with an embodiment of the present invention. A symmetric magnet array 406 includes Y magnets 414 and X magnets 418. X magnets 414 may generally be arranged in a sub-array, and Y magnets 414 may generally be arranged in sub-arrays. X magnets 418 are arranged to cooperate with X coils (not shown) to provide a relatively high acceleration to a stage (not shown) along an x-axis, while Y magnets 414 are arranged to cooperate with Y coils (not shown) to provide a relatively low acceleration to the stage along a y-axis. Y magnets 414 are also arranged to provide levitation of a stage (not shown) relative to a z-axis, and to provide compensation for pitching and rolling motions of the stage. Further, Y magnet sub-arrays 414 may be arranged to cooperate with Y coils of a coil array (not shown) to provide a yawing force about a z-axis by utilizing two forces generated by each Y magnet sub-array 414.

In the described embodiment, Y coils (not shown) of the planar motor that includes symmetric magnet array 406 generate less force than is generated by X coils (not shown) of the planar motor. As such, X magnets 418 may be thicker than Y magnets 414. That is, a dimension of X magnets 418 along a z-axis may be greater than a dimension of Y magnets 414 along the z-axis. When the thickness of Y magnets 414 is less than the thickness of X magnets 418, the overall weight of a stage system may be reduced.

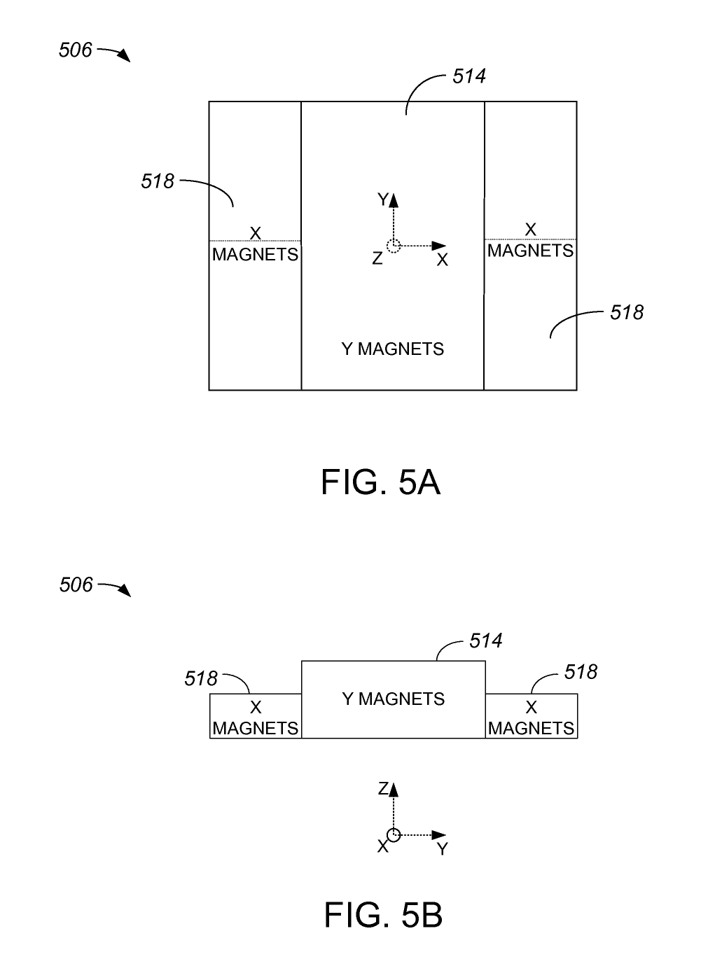

A symmetric magnet array that is configured to support relatively high acceleration of a stage along a y-axis, and has magnets of different thicknesses, will be described with respect to FIGS. 5A and 5B. FIG. 5A is a diagrammatic top-view representation of a symmetric magnet array that is configured to support relatively high acceleration along a y-axis, and FIG. 5B is a diagrammatic side-view representation of the symmetric magnet array in accordance with an embodiment of the present invention. A symmetric magnet array 506 includes X magnets 518 which are generally arranged in sub-arrays and Y magnets 514 which are generally arranged in a sub-array. Y magnets 514 are arranged to cooperate with Y coils (not shown) to provide a relatively high acceleration to a stage (not shown) along a y-axis, while X magnets 518 are arranged to cooperate with X coils (not shown) to provide a relatively low acceleration to the stage along an x-axis. X magnets 518 are also arranged to provide levitation of a stage (not shown) relative to a z-axis, and to provide compensation for pitching and rolling motions of the stage. Further, X magnet sub-arrays 518 may be arranged to cooperate with X coils of a coil array (not shown) to provide a yawing force about a z-axis by utilizing two forces generated by each X magnet sub-array 518.

In the described embodiment, X coils (not shown) of the planar motor that includes symmetric magnet array 506 generate less force than is generated by Y coils (not shown) of the planar motor. Therefore, Y magnets 514 may be thicker than X magnets 518. That is, a dimension of Y magnets 514 along a z-axis may be greater than a dimension of X magnets 518 along the z-axis. When the thickness of X magnets 518 is less than the thickness of Y magnets 514, the overall weight of a stage system which includes symmetric magnet array 506 may be reduced.

As previously mentioned, the configuration of a coil array of a planar motor which includes at least one symmetric magnet array may vary widely. By way of example, X coils and Y coils of a coil array may be in separate but adjacent layers, or groups of X coils and groups of Y coils of a coil array may be arranged in a substantially single layer.

FIG. 6A is a diagrammatic representation of a first coil array in which X coils and Y coils are arranged in adjacent layers relative to a z-axis in accordance with an embodiment of the present invention. A first coil array 610 that is part of a planar motor includes a set of X coils 622 and a set of Y coils 626. Set of X coils 622 is arranged over set of Y coils 626 relative to a z-axis.

FIG. 6B is a diagrammatic representation of a second coil array in which X coils and Y coils are arranged in adjacent layers relative to a z-axis in accordance with an embodiment of the present invention. A second coil array 610′ that is part of a planar motor includes set of X coils 622 and set of Y coils 626. Set of X coils 622, as shown, is arranged under set of Y coils 626 relative to a z-axis.

With respect to FIG. 7, a coil array in which groups of X coils and groups of Y coils are adjacent to each other in an xy-plane will be described in accordance with an embodiment of the present invention. A coil array 710 that is part of a planar motor is arranged as a substantially single layer of coils with respect to a plane defined by an x-axis and a y-axis. Groups of X coils 722, or coils arranged to cooperate with X magnets to generate force relative to the x-axis, and groups of Y coils 726, or coils arranged to cooperate with Y magnets to generate force relative to the y-axis, are arranged such that each groups of X coils 722 and groups of Y coils 726 are adjacent to each other. Groups of X coils 722 and groups of Y coils 726 may generally be arranged in a checkerboard pattern. As shown, each group of X coils 722 includes approximately three coils and each group of Y coils 726 includes approximately three coils. It should be appreciated, however, that the number of coils included in each group of X coils 722 and each group of Y coils 726 may vary widely.

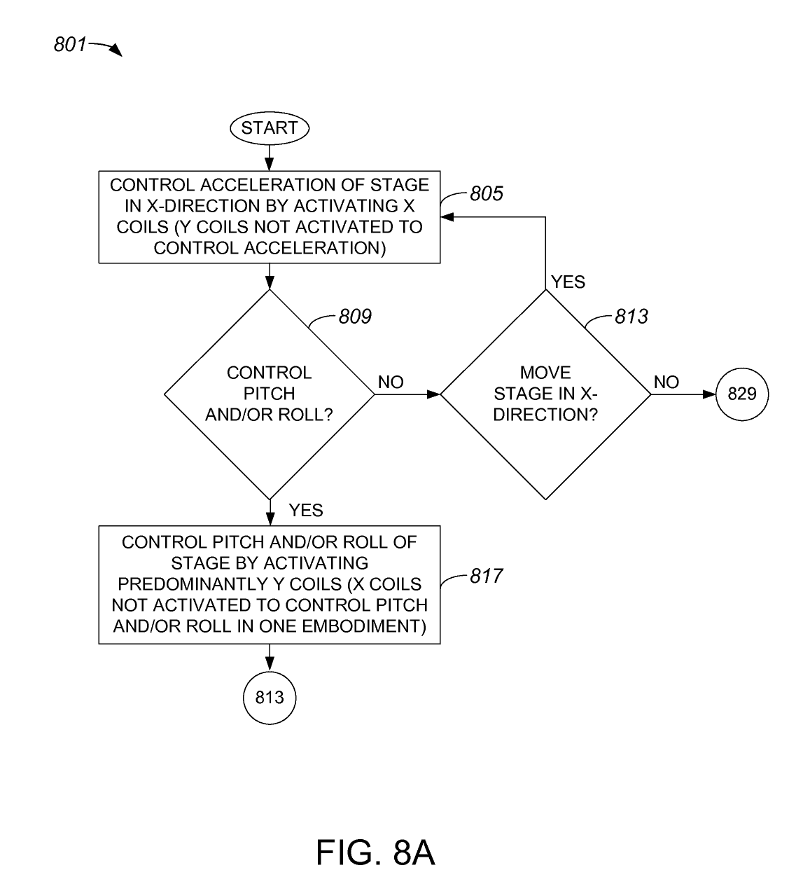

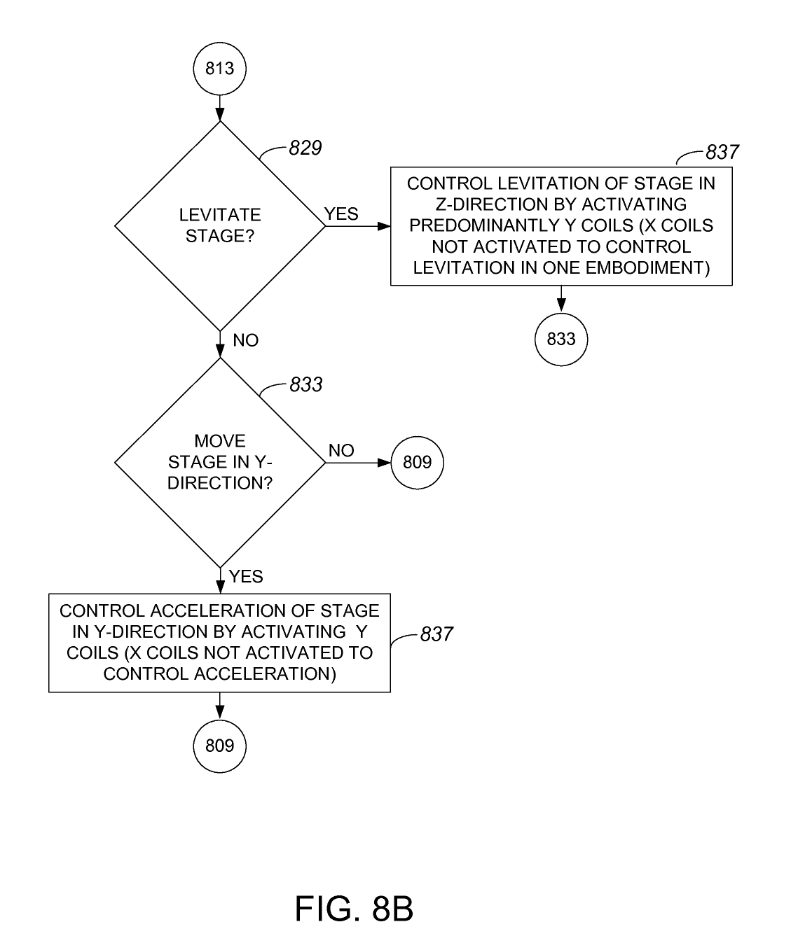

FIGS. 8A and 8B are a process flow diagram which illustrates a method of driving and controlling a stage, e.g., a stage that is arranged to have greater acceleration along an x-axis than along a y-axis, with a higher efficiency planar motor in accordance with an embodiment of the present invention. A process 801 of driving and controlling a stage arranged to have a greater acceleration in an x-direction than in a y-direction begins at step 805 in which acceleration of a stage is controlled in an x-direction by activating X coils of a higher efficiency planar motor. It should be appreciated that Y coils of the higher efficiency planar motor are generally not activated to support acceleration of the stage in the x-direction.

A determination is made in step 809 as to whether pitch and/or roll, i.e., rotational motion about an x-axis or a y-axis, is to be controlled. That is, it is determined whether the stage is undergoing pitching and/or rolling motion. If it is determined that pitch and/or roll motion is not to be controlled, process flow moves to step 813 in which it is determined if the stage is to move, e.g., accelerate, in an x-direction. If it is determined that the stage is to be moved, process flow returns to step 805 in which the acceleration of the stage in an x-direction is controlled by activating X coils.

Alternatively, if it is determined in step 813 that the stage is not to be moved in the x-direction, then a determination is made in step 829 as to whether the stage is to be levitated. In other words, it is determined whether the position of the stage is to be adjusted relative to a z-direction. If the determination is that the stage is not to be levitated, a determination is made in step 833 as to whether the stage is to move in a y-direction.

If it is determined that the stage is not to be moved in the y-direction, then process flow returns to step 809 in which it is determined whether pitch and/or roll motion of the stage is to be controlled. On the other hand, if it is determined in step 833 that the stage is to move in the y-direction, the acceleration of the stage in the y-direction is controlled by activating Y coils. It should be appreciated that when acceleration in a y-direction is controlled by Y coils, X coils are typically not activated. Once acceleration of the stage in the y-direction is controlled, process flow returns to step 809 in which it is determined whether pitch and/or roll motion of the stage is to be controlled.

Returning to step 829 and the determination of whether the stage is to be levitated, if it is determined that the stage is to be levitated, the implication is that motion of the stage in a z-direction is to be controlled. Accordingly, in step 837, levitation of the stage in the z-direction is controlled by activating predominantly Y coils. In the described embodiment, X coils are not activated to levitate the stage. It should be appreciated, however, that in some embodiments, Y coils may be activated to take up a significant percentage of the load associated with levitating the stage, while X coils may be activated to take up a relatively small percentage of the load associated with levitating the stage. After Y coils are activated to control levitation, process flow moves from step 837 to step 833 in which it is determined whether the stage is to move in a Y-direction.

Referring back to step 809 in which it is determined whether pitch and/or roll motion of the stage is to be controlled, if the determination is that pitch and/or roll is to be controlled, Y coils are predominantly activated in step 817. In one embodiment, when Y coils are activated to control pitch and/or roll motion of the stage, X coils are not activated to control pitch and/or roll motion of the stage. In another embodiment, when Y coils are activated to control pitch and/or roll motion of the stage, X coils may be activated to take up relatively small amount of the load associated with controlling pitch and/or roll motion, while Y coils may be activated to take up a majority of the load associated with controlling pitch and/or roll motion. Once Y coils are activated to control pitch and/or roll motion of the stage, process flow moves to step 813 in which it is determined whether the stage is to move in an x-direction.

It should be appreciated that while FIGS. 8A and 8B relate to a higher efficiency planar motor which uses Y coils to control levitation as well as pitch and/or roll, some higher efficiency planar motors may instead use X coils to control levitation as well as pitch and/or roll. As discussed above, in one embodiment, when X coils control levitation as well as pitch and/or roll, Y coils are not activated to control levitation, pitch, and/or roll.

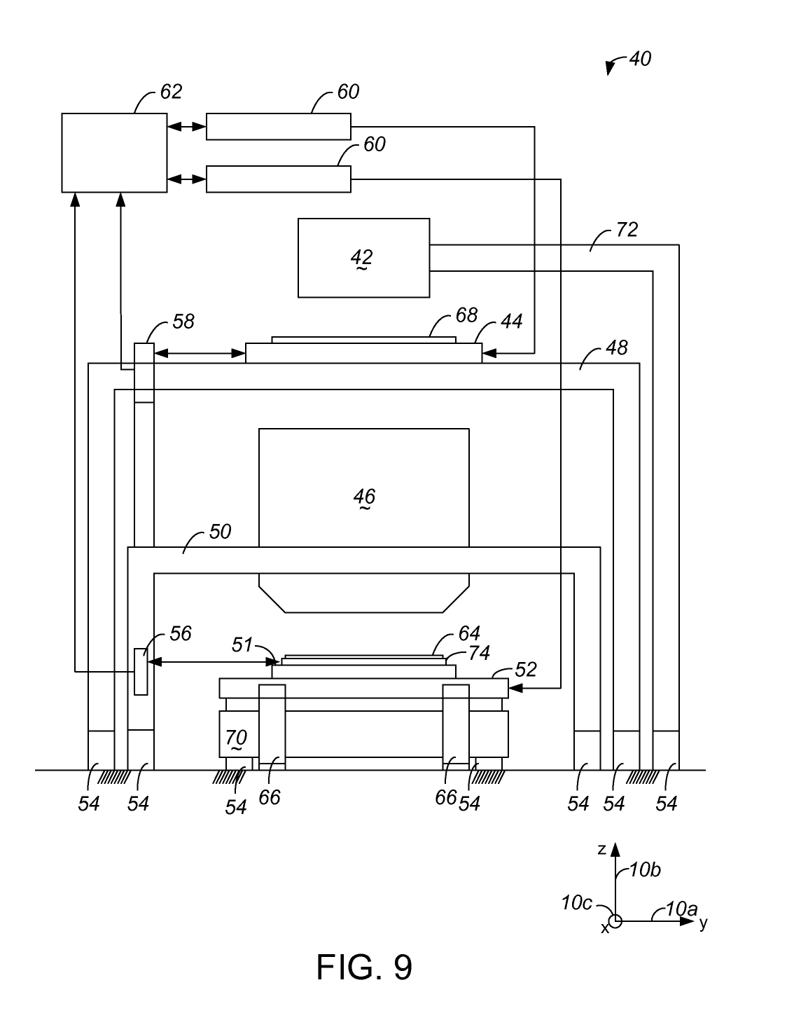

With reference to FIG. 9, a photolithography apparatus which may include a high efficiency planar motor as described above will be described in accordance with an embodiment of the present invention. A photolithography apparatus (exposure apparatus) 40 includes a wafer positioning stage 52 that may be driven by a planar motor (not shown), as well as a wafer table 51 that is magnetically coupled to wafer positioning stage 52 by utilizing an EI-core actuator, a voice coil motor, or any other suitable actuator. The planar motor which drives wafer positioning stage 52 generally uses an electromagnetic force generated by magnets and corresponding armature coils arranged in two dimensions.

A wafer 64 is held in place on a wafer holder or chuck 74 which is coupled to wafer table 51. Wafer positioning stage 52 is arranged to move in multiple degrees of freedom, e.g., in up to six degrees of freedom, under the control of a control unit 60 and a system controller 62. In one embodiment, wafer positioning stage 52 may include a plurality of actuators and have a configuration as described above. The movement of wafer positioning stage 52 allows wafer 64 to be positioned at a desired position and orientation relative to a projection optical system 46.

Wafer table 51 may be levitated in a z-direction 10b by any number of voice coil motors (not shown), e.g., three voice coil motors. In one described embodiment, at least three magnetic bearings (not shown) couple and move wafer table 51 along a y-axis 10a. The motor array of wafer positioning stage 52 is typically supported by a base 70. Base 70 is supported to a ground via isolators 54. Reaction forces generated by motion of wafer stage 52 may be mechanically released to a ground surface through a frame 66. One suitable frame 66 is described in JP Hei 8-166475 and U.S. Pat. No. 5,528,118, which are each herein incorporated by reference in their entireties.

An illumination system 42 is supported by a frame 72. Frame 72 is supported to the ground via isolators 54. Illumination system 42 includes an illumination source, which may provide a beam of light that may be reflected off of a reticle. In one embodiment, illumination system 42 may be arranged to project a radiant energy, e.g., light, through a mask pattern on a reticle 68 that is supported by and scanned using a reticle stage 44 which may include a coarse stage and a fine stage, or which may be a single, monolithic stage. The radiant energy is focused through projection optical system 46, which is supported on a projection optics frame 50 and may be supported the ground through isolators 54. Suitable isolators 54 include those described in JP Hei 8-330224 and U.S. Pat. No. 5,874,820, which are each incorporated herein by reference in their entireties.

A first interferometer 56 is supported on projection optics frame 50, and functions to detect the position of wafer table 51. Interferometer 56 outputs information on the position of wafer table 51 to system controller 62. In one embodiment, wafer table 51 has a force damper which reduces vibrations associated with wafer table 51 such that interferometer 56 may accurately detect the position of wafer table 51. A second interferometer 58 is supported on projection optical system 46, and detects the position of reticle stage 44 which supports a reticle 68. Interferometer 58 also outputs position information to system controller 62.

It should be appreciated that there are a number of different types of photolithographic apparatuses or devices. For example, photolithography apparatus 40, or an exposure apparatus, may be used as a scanning type photolithography system which exposes the pattern from reticle 68 onto wafer 64 with reticle 68 and wafer 64 moving substantially synchronously. In a scanning type lithographic device, reticle 68 is moved perpendicularly with respect to an optical axis of a lens assembly (projection optical system 46) or illumination system 42 by reticle stage 44. Wafer 64 is moved perpendicularly to the optical axis of projection optical system 46 by a wafer stage 52. Scanning of reticle 68 and wafer 64 generally occurs while reticle 68 and wafer 64 are moving substantially synchronously.

Alternatively, photolithography apparatus or exposure apparatus 40 may be a step-and-repeat type photolithography system that exposes reticle 68 while reticle 68 and wafer 64 are stationary, i.e., at a substantially constant velocity of approximately zero meters per second. In one step and repeat process, wafer 64 is in a substantially constant position relative to reticle 68 and projection optical system 46 during the exposure of an individual field. Subsequently, between consecutive exposure steps, wafer 64 is consecutively moved by wafer positioning stage 52 perpendicularly to the optical axis of projection optical system 46 and reticle 68 for exposure. Following this process, the images on reticle 68 may be sequentially exposed onto the fields of wafer 64 so that the next field of semiconductor wafer 64 is brought into position relative to illumination system 42, reticle 68, and projection optical system 46.

It should be understood that the use of photolithography apparatus or exposure apparatus 40, as described above, is not limited to being used in a photolithography system for semiconductor manufacturing. For example, photolithography apparatus 40 may be used as a part of a liquid crystal display (LCD) photolithography system that exposes an LCD device pattern onto a rectangular glass plate or a photolithography system for manufacturing a thin film magnetic head.

The illumination source of illumination system 42 may be g-line (436 nanometers (nm)), i-line (365 nm), a KrF excimer laser (248 nm), an ArF excimer laser (193 nm), and an F2-type laser (157 nm). Alternatively, illumination system 42 may also use charged particle beams such as x-ray and electron beams. For instance, in the case where an electron beam is used, thermionic emission type lanthanum hexaboride (LaB6) or tantalum (Ta) may be used as an electron gun. Furthermore, in the case where an electron beam is used, the structure may be such that either a mask is used or a pattern may be directly formed on a substrate without the use of a mask.

With respect to projection optical system 46, when far ultra-violet rays such as an excimer laser are used, glass materials such as quartz and fluorite that transmit far ultra-violet rays is preferably used. When either an F2-type laser or an x-ray is used, projection optical system 46 may be either catadioptric or refractive (a reticle may be of a corresponding reflective type), and when an electron beam is used, electron optics may comprise electron lenses and deflectors. As will be appreciated by those skilled in the art, the optical path for the electron beams is generally in a vacuum.

In addition, with an exposure device that employs vacuum ultra-violet (VUV) radiation of a wavelength that is approximately 200 nm or lower, use of a catadioptric type optical system may be considered. Examples of a catadioptric type of optical system include, but are not limited to, those described in Japan Patent Application Disclosure No. 8-171054 published in the Official gazette for Laid-Open Patent Applications and its counterpart U.S. Pat. No. 5,668,672, as well as in Japan Patent Application Disclosure No. 10-20195 and its counterpart U.S. Pat. No. 5,835,275, which are all incorporated herein by reference in their entireties. In these examples, the reflecting optical device may be a catadioptric optical system incorporating a beam splitter and a concave minor. Japan Patent Application Disclosure (Hei) No. 8-334695 published in the Official gazette for Laid-Open Patent Applications and its counterpart U.S. Pat. No. 5,689,377, as well as Japan Patent Application Disclosure No. 10-3039 and its counterpart U.S. Pat. No. 5,892,117, which are all incorporated herein by reference in their entireties. These examples describe a reflecting-refracting type of optical system that incorporates a concave mirror, but without a beam splitter, and may also be suitable for use with the present invention.

The present invention may be utilized, in one embodiment, in an immersion type exposure apparatus if suitable measures are taken to accommodate a fluid. For example, PCT patent application WO 99/49504, which is incorporated herein by reference in its entirety, describes an exposure apparatus in which a liquid is supplied to a space between a substrate (wafer) and a projection lens system during an exposure process. Aspects of PCT patent application WO 99/49504 may be used to accommodate fluid relative to the present invention.

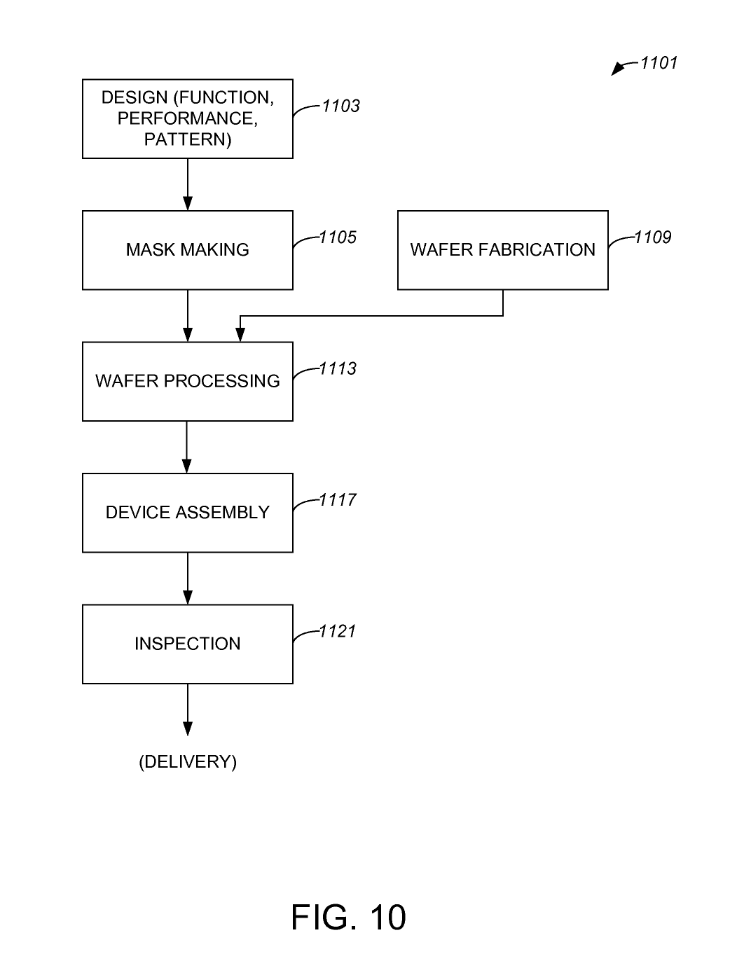

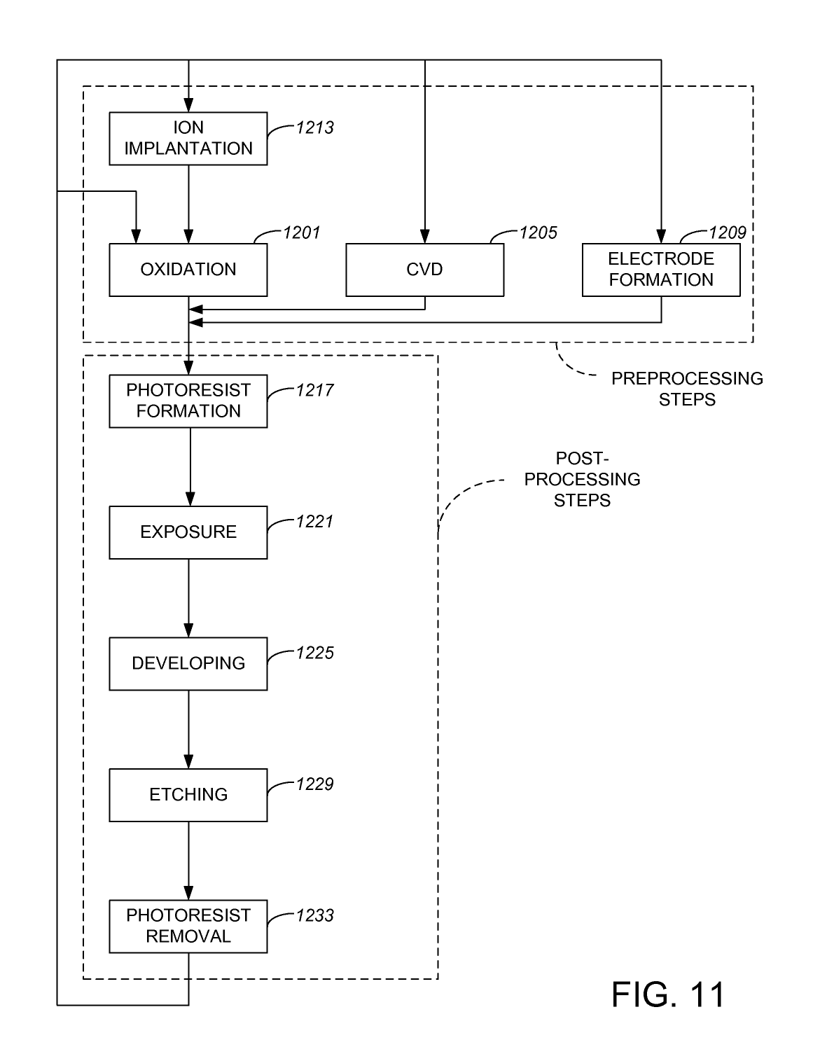

Further, semiconductor devices may be fabricated using systems described above, as will be discussed with reference to FIG. 10. FIG. 10 is a process flow diagram which illustrates the steps associated with fabricating a semiconductor device in accordance with an embodiment of the present invention. A process 1101 of fabricating a semiconductor device begins at step 1103 in which the function and performance characteristics of a semiconductor device are designed or otherwise determined. Next, in step 1105, a reticle or mask in which has a pattern is designed based upon the design of the semiconductor device. It should be appreciated that in a substantially parallel step 1109, a wafer is typically made from a silicon material. In step 1113, the mask pattern designed in step 1105 is exposed onto the wafer fabricated in step 1109. One process of exposing a mask pattern onto a wafer will be described below with respect to FIG. 11. In step 1117, the semiconductor device is assembled. The assembly of the semiconductor device generally includes, but is not limited to including, wafer dicing processes, bonding processes, and packaging processes. Finally, the completed device is inspected in step 1121. Upon successful completion of the inspection in step 1121, the completed device may be considered to be ready for delivery.

FIG. 11 is a process flow diagram which illustrates the steps associated with wafer processing in the case of fabricating semiconductor devices in accordance with an embodiment of the present invention. In step 1201, the surface of a wafer is oxidized. Then, in step 1205 which is a chemical vapor deposition (CVD) step in one embodiment, an insulation film may be formed on the wafer surface. Once the insulation film is formed, then in step 1209, electrodes are formed on the wafer by vapor deposition. Then, ions may be implanted in the wafer using substantially any suitable method in step 1213. As will be appreciated by those skilled in the art, steps 1201-1213 are generally considered to be preprocessing steps for wafers during wafer processing. Further, it should be understood that selections made in each step, e.g., the concentration of various chemicals to use in forming an insulation film in step 1205, may be made based upon processing requirements.

At each stage of wafer processing, when preprocessing steps have been completed, post-processing steps may be implemented. During post-processing, initially, in step 1217, photoresist is applied to a wafer. Then, in step 1221, an exposure device may be used to transfer the circuit pattern of a reticle to a wafer. Transferring the circuit pattern of the reticle of the wafer generally includes scanning a reticle scanning stage which may, in one embodiment, include a force damper to dampen vibrations.

After the circuit pattern on a reticle is transferred to a wafer, the exposed wafer is developed in step 1225. Once the exposed wafer is developed, parts other than residual photoresist, e.g., the exposed material surface, may be removed by etching in step 1229. Finally, in step 1233, any unnecessary photoresist that remains after etching may be removed. As will be appreciated by those skilled in the art, multiple circuit patterns may be formed through the repetition of the preprocessing and post-processing steps.

Although only a few embodiments of the present invention have been described, it should be understood that the present invention may be embodied in many other specific forms without departing from the spirit or the scope of the present invention. By way of example, although embodiments of suitable magnet arrays that are symmetric about both an x-axis and a y-axis have been shown, suitable magnet arrays that are symmetric about both an x-axis and a y-axis are not limited to the embodiments shown. In other words, any suitable magnet array that is symmetric about both an x-axis and a y-axis may be a suitable magnet array configuration that increases the efficiency with which a stage may be driven.

Symmetric coil arrays may also be used to interact with magnets that may be uniformly arranged, e.g., with north and south poles pointing in the same direction, or magnets that may be arranged in a checkerboard pattern, e.g., a checkerboard pattern of Halbach arrays.

While levitation, or motion with respect to a z-axis, of a stage has been described as being provided by substantially only X coils or by substantially only Y coils of a planar motor, it should be appreciated that levitation may instead be primarily provided by one type of coil and supplemented by another type of coil. That is, levitation may be primarily supported by X coils with a relatively small contribution from Y coils, or levitation may be primarily supported by Y coils with a relatively small contribution from X coils. For an embodiment in which it is beneficial to reduce the thickness of X magnets or where an effective requirement for X forces is relatively low, levitation may be primarily supported by X coils with a relatively small contribution from Y coils. Similarly, for an embodiment in which it is beneficial to reduce the thickness of Y magnets or where an effective requirement for Y forces is relatively low, levitation may be primarily supported by Y coils with a relatively small contribution from X coils.

Pitching and rolling motion of a stage has been described as being provided by substantially only X coils or by substantially only Y coils of a planar motor. In some instances, pitching and rolling motion of a stage may instead be primarily provided by one type of coil and supplemented by another type of coil. That is, pitching and rolling may be primarily supported by X coils with a relatively small contribution from Y coils, or pitching and rolling may be primarily supported by Y coils with a relatively small contribution from X coils. In one embodiment, if there is a benefit to reducing the thickness of X magnets, pitching and rolling may be primarily supported by X coils with a relatively small contribution from Y coils. Similarly, for an embodiment in which there is a benefit to reducing the thickness of Y magnets, pitching and rolling may be primarily supported by Y coils with a relatively small contribution from X coils.

In one embodiment, one type of magnet may be used to support levitation while another type of magnet may be used to compensate for pitch and/or roll motion, as well as yaw motion. For example, X magnets may be used to support levitation while Y magnets may be used to compensate for pitch and/or roll motion, or Y magnets may be used to support levitation while X magnets may be used to compensate for pitch and/or roll motion.

A stage may be any suitable stage. For instance, a stage may be a wafer stage, a reticle stage, an exposure stage, or a measurement stage. It should be appreciated that for a measurement stage, Y motion, or motion along a y-axis, is typically predominant during a scrum motion, and there may be a greater surface area associated with Y magnets than with X magnets on the measurement stage.

In general, as discussed above with respect to FIGS. 1A and 1B, either coils or magnets may be mounted on a stage. If an actuator or motor is such that coils are mounted on a stage, then magnets may be mounted either above or below the stage. Alternatively, if an actuator or motor is such that magnets are mounted on a stage, then coils may be mounted either above or below the stage.

As described above, either an X magnet array or a Y magnet array may generally be used to provide a Z force to a stage, and to compensate for pitching and rolling of the stage. For example, levitation with respect to a z-axis, pitch, yaw, and roll of an exposure stage may be substantially controlled with Y coils, while levitation with respect to a z-axis, pitch, yaw, and roll of a measurement stage may be substantially controlled with X coils. It should be appreciated that, as mentioned above, one set of magnets on a stage may be used to control levitation while another set of magnets on the stage may be used to control pitch, yaw, and roll motion. Different stages in an overall stage system may use different magnets for the control of levitation and/or pitch, yaw, and roll. The choice of which magnets to use for different purposes may be substantially optimized, in one embodiment, based on efficiency.

A coil array has generally been described as including either separate layers of X coils and Y coils, or a substantially single layer that contains a checkerboard pattern of X coils and Y coils. In one embodiment, a coil array may include two or more layers where the layers each include a checkerboard pattern of X coils and Y coils without departing from the spirit or the scope of the present invention.

Although a stage system which includes an exposure stage and a measurement stage has been described as suitable for use with a higher efficiency planar motor, a higher efficiency planar motor may generally be applied to any stage system. By way of example, a higher efficiency planar motor that includes symmetric magnet arrays may be used with respect to a stage system that includes two or more wafer stages. It should be appreciated that in a stage system that includes two or more stages, symmetric magnet arrays associated with each of the stages may either be substantially the same or may be different. For instance, for a stage system that includes two wafer stages, each of the wafer stages may have a symmetric magnet array arranged to support a relatively high acceleration along an x-axis, or one of the wafer stages may have a symmetric magnet array arranged to support a relatively high acceleration along an x-axis while the other wafer stage may have a symmetric magnet array arranged to support relatively high acceleration along a y-axis.

To control six degrees of freedom, either an X magnet array or a Y magnet array may be divided into two or more sub-arrays which may be individually controlled. It should be appreciated, however, that X magnet arrays and/or Y magnet arrays are not limited to being divided into two of more sub-arrays which may be individually controlled.

Some planar motor designs may use one type of coil for generating X forces and Y forces. That is, some motor designs do not utilize distinct coils for generating X forces and Y forces. In such a case, certain coils may be activated to provide a relatively high acceleration along one axis, and other coils may be activated to provide levitation, pitch compensation, and roll compensation, as well as yaw compensation.

While magnets of different thicknesses have generally been described as having thicker magnets associated with a relatively high acceleration, it should be appreciated that thicker magnets are not limited to being associated with a relatively high acceleration. For example, for a stage that supports relatively high acceleration in a Y direction, Y magnets may be thicker than X magnets. It should be appreciated, however, that thicker magnets are not limited to being associated with a relatively high acceleration. For instance, some applications may utilize magnets of different thicknesses for other reasons without departing from the spirit or the scope of the present invention.

The many features of the embodiments of the present invention are apparent from the written description. Further, since numerous modifications and changes will readily occur to those skilled in the art, the present invention should not be limited to the exact construction and operation as illustrated and described. Hence, all suitable modifications and equivalents may be resorted to as falling within the spirit or the scope of the present invention.

What is claimed is:

1. A stage apparatus comprising:
a first surface;
a second surface;
an overall magnet array, the overall magnet array being mounted on the first surface, the overall magnet array including an X magnet array and a Y magnet array, the X magnet array including at least one X magnet, the Y magnet array including at least one Y magnet; and
a plurality of coils, the plurality of coils being mounted on the second surface, the plurality of coils including at least one first coil arranged to cooperate with the X magnet array to control force on the first surface along an x-axis, the plurality of coils further including at least one second coil arranged to cooperate with the Y magnet array to control force on the first surface along a y-axis, wherein the at least one second coil is further arranged to cooperate with the overall magnet array to control at least one normal force applied to the first surface in a direction normal to the first surface and wherein a majority of the at least one normal force is produced by the at least one second coil.

2. The stage apparatus of claim 1 wherein the first surface is a surface of a stage and the second surface is located at a distance from the first surface relative to a z-axis.

3. The stage apparatus of claim 1 wherein the second surface is a surface of a stage and the second surface is located at a distance from the first surface relative to a z-axis.

4. The stage apparatus of claim 1 wherein the overall magnet array is symmetric with respect to the x-axis and with respect to the y-axis.

5. The stage apparatus of claim 4 wherein the Y magnet array includes a first portion and a second portion, and wherein the X magnet array is arranged substantially between the first portion and the second portion.

6. The stage apparatus of claim 1 wherein the at least one second coil is further is still further arranged to cooperate with the overall magnet array to control at least one selected from a group including rotational motion of the first surface with respect to the x-axis, rotational motion of the first surface with respect to the y-axis, and rotational motion of the first surface with respect to a z-axis.

7. The stage apparatus of claim 1 wherein the at least one X magnet has a first thickness relative to a z-axis and the at least one Y magnet has a second thickness relative to the y-axis, wherein the first thickness is greater than the second thickness.

8. The stage apparatus of claim 1 wherein approximately all normal forces applied to the first surface are generated using the at least one second coil.

9. An exposure apparatus comprising the stage apparatus of claim 1.

10. A wafer formed using the exposure apparatus of claim 8.

11. An exposure apparatus comprising the stage apparatus of claim 1 wherein the first surface is associated with a first stage, and wherein the plurality of coils is further arranged to cooperate with a second stage magnet array associated with a second stage to drive the second stage.

12. An exposure apparatus comprising the stage apparatus of claim 1 wherein the second surface is associated with a first stage, and wherein the overall magnet array is further arranged to cooperate with a set of coils associated with a second stage to drive the second stage.

13. A stage apparatus comprising:
a first surface;
a second surface;
an overall magnet array, the overall magnet array being mounted on the first surface, the overall magnet array including an X magnet array and a Y magnet array, the X magnet array including at least one X magnet, the Y magnet array including at least one Y magnet; and
a plurality of coils, the plurality of coils being mounted on the second surface, the plurality of coils including at least one first coil arranged to cooperate with the X magnet array to control force on the first surface along an x-axis, the plurality of coils further including at least one second coil arranged to cooperate with the Y magnet array to control force on the first surface along a y-axis, wherein forces applied to the first surface relative to a z-axis are applied through cooperation between the at least one first coil and the overall magnet array, and wherein the at least one second coil is not activated to cooperate with the overall magnet array when the forces applied to the first surface relative to the z-axis are applied through the cooperation between the at least one first coil and the overall magnet array.

14. The stage apparatus of claim 13 wherein the first surface is a surface of a stage and the second surface is located at a distance from the first surface relative to the z-axis.

15. The stage apparatus of claim 13 wherein the second surface is a surface of a stage and the second surface is located at a distance from the first surface relative to the z-axis.

16. The stage apparatus of claim 13 wherein the overall magnet array is symmetric with respect to the x-axis and with respect to the y-axis.

17. The stage apparatus of claim 16 wherein the X magnet array includes a first portion and a second portion, and wherein the Y magnet array is arranged substantially between the first portion and the second portion.

18. The stage apparatus of claim 13 wherein the at least one first coil is further arranged to cooperate with the overall magnet array to control at least one selected from a group including rotational motion of the first surface with respect to the x-axis, rotational motion of the first surface with respect to the y-axis, and rotational motion of the first surface with respect to a z-axis.

19. The stage apparatus of claim 13 wherein the at least one X magnet has a first thickness relative to the z-axis and the at least one Y magnet has a second thickness relative to the y-axis, wherein the second thickness is greater than the first thickness.

20. An exposure apparatus comprising the stage apparatus of claim 13.

21. A wafer formed using the exposure apparatus of claim 20.

22. A stage apparatus comprising:
a first surface;
a second surface;
an overall magnet array, the overall magnet array being mounted on the first surface, the overall magnet array including an X magnet array and a Y magnet array, the X magnet array including at least one X magnet, the Y magnet array including at least one Y magnet; and
a plurality of coils, the plurality of coils being mounted on the second surface, the plurality of coils including at least one X coil and at least one Y coil, the at least one X coil being arranged to cooperate with the X magnet array to cause the first surface to accelerate along an x-axis, the at least one Y coil being arranged to cooperate with the Y magnet array to cause the first surface to accelerate along a y-axis, to levitate with respect to a z-axis, to provide pitch compensation, to provide yaw compensation, and to provide roll compensation, wherein the at least one X coil substantially does not cooperate with the X magnet array to cause the first surface to accelerate along the y-axis, to levitate with respect to the z-axis, to provide yaw compensation, to provide the pitch compensation, nor to provide roll compensation.

23. A stage apparatus comprising:
a first member;
a second member; and
a moving device that moves the first member relative to the second member, the moving device including a first part and a second part;
wherein the first part includes a first magnet array, the first magnet array being mounted on the first member, the first magnet array including an X magnet array, the X magnet array including at least one X magnet; and a first plurality of coils, the first plurality of coils being mounted on the second member, the first plurality of coils including at least a first coil arranged to cooperate with the X magnet array to control force on the first surface along an x-axis, and
wherein the second part includes a second magnet array, the second magnet array being mounted on the first member, the second magnet array including a Y magnet array, the Y magnet array including at least one Y magnet; and a second plurality of coils, the second plurality of coils being mounted on the second member, the second plurality of coils including at least a second coil arranged to cooperate with the Y magnet array to control force on the first member along a y-axis, wherein the at least second coil is further arranged to cooperate with the second magnet array to control force applied to the first member along a z-axis, about an x-axis, about a y-axis, and about a z-axis.

24. The stage apparatus of claim 23 wherein the one of the first magnet array and the second magnet array is symmetric with respect to the x-axis and with respect to the y-axis.

25. The stage apparatus of claim 23 wherein the Y magnet array includes a first portion and a second portion, and wherein the X magnet array is arranged substantially between the first portion and the second portion.

26. The stage apparatus of claim 23 wherein the at least one X magnet has a first thickness relative to a z-axis and the at least one Y magnet has a second thickness relative to the y-axis, wherein the first thickness is greater than the second thickness.

27. An exposure apparatus comprising the stage apparatus of claim 23.
